(19) United States
(12) Patent Application Publication
(10) Pub. No.: US 2019/0386215 A1
(43) Pub. Date: Dec. 19, 2019

(54) STRIPPING METHOD OF FLEXIBLE OLED DISPLAY DEVICE

(71) Applicant: Wuhan China Star Optoelectronics Technology Co., Ltd, Wuhan, Hubei (CN)

(72) Inventor: Xia CHEN, Wuhan, Hubei (CN)

(21) Appl. No.: 15/740,769

(22) PCT Filed: Dec. 6, 2017
(86) PCT No.: PCT/CN2017/114758

§ 371 Date: Dec. 28, 2017

(30) Foreign Application Priority Data
Aug. 18, 2017 (CN) 201710713438.8

(51) Int. Cl. H01L 51/00; H01L 51/56

(52) U.S. Cl. CPC H01L 51/003; H01L 51/0097; H01L 27/3244; H01L 2251/5338; H01L 51/56

(57) ABSTRACT

The present disclosure provides a stripping method of a flexible OLED display, including the following steps: coating a thin film layer on a side of a carrier substrate; sequentially forming a flexible substrate layer, a low-temperature polysilicon layer, a light-emitting layer and an encapsulation layer on the thin film layer; and heating the thin film layer until the flexible substrate layer is peeled off from the carrier substrate to obtain a flexible OLED display device. The stripping method provided by the present disclosure can simply separate the flexible OLED display device from the carrier substrate, it will not appear difficult to peel off between the flexible substrate layer and the carrier substrate of the display device and will not cause the thin film layer in the OLED display device to be broken due to the pulling and improve the yield of the peeling process of the OLED display device.

### RELATED APPLICATIONS

The present application is a National Phase of International Application Number PCT/CN2017/114758, filed Dec. 6, 2017, and claims the priority of China Application CN 201710713438.8, filed Aug. 18, 2017.

### FIELD OF THE DISCLOSURE

The present disclosure relates to an OLED display technology field, and more particularly to a stripping method of a flexible OLED display device.

### BACKGROUND OF THE DISCLOSURE

The flexible OLED display device is manufactured by a traditional method. First, coating PI on the glass substrate and processing LTPS, and after evaporating EL and packaging, the PI layer is separated from the glass substrate by laser stripping technology. In the preparation of a flexible OLED, the structure of each layer is first finished on the glass substrate, and the laser is irradiated on the glass substrate by the laser stripping technology to separate the PI layer from the glass substrate. Stripping process not only the high cost of laser equipment, and if cannot precisely control the laser energy, the laser will damage the OLED display device. And the surface of the glass substrate has problems of poor image display and particles on the surface of the glass substrate, which leads to uneven laser energy received on the surface of the PI layer. It is difficult to peel off the portion where the laser of the surface received is less. In the peeling process, there is a possibility that pulling causes the film layer in the OLED display device (e.g., the EL layer, i.e., the light-emitting layer) to rupture, resulting in reducing the yield of the peeling process.

### SUMMARY OF THE DISCLOSURE

In order to solve the above technical problem, the present disclosure provides a stripping method of a flexible OLED display device, which can simply peel the flexible substrate layer of the OLED display device and the carrier substrate to improve the stripping process yield of the OLED display device.

The stripping method of a flexible OLED display provided by the present disclosure includes the following steps:

coating a thin film layer on a side of a carrier substrate, wherein the carrier substrate is one of a glass plate, an acrylic plate and a rough metal plate, the material of the thin film layer is at least one of naphthalene, phosphorus pentachloride, amine compounds, polyalcohol compounds and paraffin wax;

forming a flexible substrate layer on the thin film layer;

forming a low-temperature polysilicon layer on the flexible substrate layer;

forming a light-emitting layer on the low-temperature polysilicon layer;

forming an encapsulation layer on the light-emitting layer; and

heating the thin film layer until the flexible substrate layer is peeled off from the carrier substrate to obtain a flexible OLED display device.

Preferably, the following steps are further included:

wherein the encapsulation layer includes SiₓO_{y} and/or SiN, where x≥1 and y≥1.

Wherein the amine compound is at least one of an aromatic amine compound or acrylamide.

Wherein the polyalcohol compound is polyethylene glycol.

Wherein the thickness of the thin film layer is nanometer level or micrometer level.

Wherein the flexible substrate layer is a transparent film made of at least one material selected from the group consisting of polyethylene, polypropylene, polystyrene, polyethylene terephthalate, polyethylene naphthalate, and polyimide.

Wherein the light-emitting layer includes an organic EL layer.

Wherein when the thin film layer is made of at least one material of naphthalene and phosphorus pentachloride, vacuum assisted processing is also performed when the thin film layer is heated.

Wherein when the carrier substrate is a glass plate, a surface of the glass plate coated with the thin film layer is plasma-treated to increase the number of hydroxyl groups and the roughness of the surface thereof.

The present disclosure also provides a stripping method of a flexible OLED display device, including the following steps:

coating a thin film layer on a side of a carrier substrate, wherein the carrier substrate is one of a glass plate, an acrylic plate and a rough metal plate, the material of the thin film layer is at least one of naphthalene, phosphorus pentachloride, amine compounds, polyalcohol compounds and paraffin wax;

forming a flexible substrate layer on the thin film layer;

forming a low-temperature polysilicon layer on the flexible substrate layer;

forming a light-emitting layer on the low-temperature polysilicon layer;

forming an encapsulation layer on the light-emitting layer; and

heating the thin film layer until the flexible substrate layer is peeled off from the carrier substrate to obtain a flexible OLED display device;

wherein the encapsulation layer includes SiₓO_{y} and/or SiN, where x≥1 and y≥1.

Wherein the amine compound is at least one of an aromatic amine compound or acrylamide.

Wherein the polyalcohol compound is polyethylene glycol.

Wherein the thickness of the thin film layer is nanometer level or micrometer level.

Wherein the flexible substrate layer is a transparent film made of at least one material selected from the group consisting of polyethylene, polypropylene, polystyrene, polyethylene terephthalate, polyethylene naphthalate and polyimide.

Wherein the light-emitting layer includes an organic EL layer.

When the thin film layer is made of at least one material of naphthalene and phosphorus pentachloride, vacuum assisted processing is also performed when the thin film layer is heated.

When the carrier substrate is a glass plate, a surface of the glass plate coated with the thin film layer is plasma-treated to increase the number of hydroxyl groups and the roughness of the surface thereof.

The implementation of the present disclosure has the following beneficial effects: naphthalene, phosphorus pentachloride, amine compounds, polyalcohol compounds, paraffin and other materials made of thin film layer and the glass or acrylic plate can be bonded by chemical bonds between the glass or acrylic plate can also be bonded to the rough surface of the metal plate. And the material of the film layer has a low melting point or is easily sublimated, the thin film layer is heated to reach the corresponding melting point or sublimation temperature, melted or sublimated, and the flexible OLED display device can be separated from the carrier substrate. There will be no difficulty in peeling between the flexible substrate layer and the carrier substrate of the display device and the thin film layer in the OLED display device will not be broken due to the pulling, so as to improve the peeling rate of the OLED display device.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art, Apparently, the accompanying drawings in the following description show merely some embodiments of the present disclosure, and a person of ordinary skill in the art may still derive other drawings from these accompanying drawings without creative efforts.

FIG. 1 is a flow chart of a stripping method of a flexible OLED display device according to the present disclosure.

FIG. 2 is a structural schematic diagram of a stripping method of a flexible OLED display device according to the present disclosure.

### DETAILED DESCRIPTION OF PREFERRED EMBODIMENTS

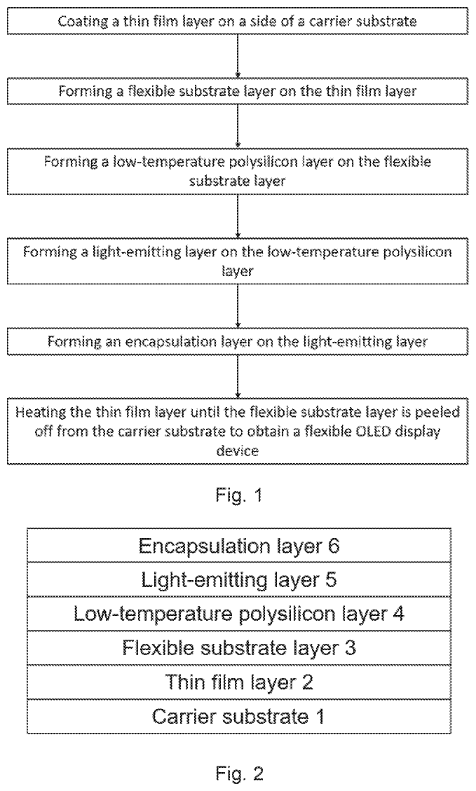

The present disclosure provides a stripping method of a flexible OLED display device. As shown in FIG. 1 and FIG. 2, the method includes the following steps:

coating a thin film layer 2 on a side of a carrier substrate 1, wherein the carrier substrate 1 is one of a glass plate, an acrylic plate and a rough metal plate, the material of the thin film layer 2 is at least one of naphthalene, phosphorus pentachloride, amine compounds, polyalcohol compounds and paraffin wax;

forming a flexible substrate layer 3 on the thin film layer 2;

forming a low-temperature polysilicon layer 4 on the flexible substrate layer 3;

forming a light-emitting layer 5 on the low-temperature polysilicon layer 4;

forming an encapsulation layer 6 on the light-emitting layer 5; and

heating the thin film layer 2 until the flexible substrate layer 3 is peeled off from the carrier substrate 1 to obtain a flexible OLED display device.

Naphthalene, phosphorus pentachloride are easy to sublimate materials, amines, polyalcohols, paraffin wax are low melting point materials, only need to be slightly heated. Generally, the heating temperature is between 30° C. and 200° C., the materials can be sublimated or melted without too high temperature, so that the carrier substrate 1 and the flexible substrate layer 3 are peeled off. The peeling operation is relatively simple and convenient, do not need laser equipment, so the cost is relatively low.

It should be noted that, heating the thin film layer 2 is not limited to directly heating the thin film layer 2, and the thin film layer 2 may also be heated under the carrier substrate 1. The way of heating the thin film layer 2 is one of laser heating, oven heating, infrared heating and electromagnetic heating.

Since the surface of the glass plate has groups such as —OH, naphthalene, phosphorus pentachloride, amine compounds, polyalcohol compounds, paraffin and other materials can be directly bonded to the glass substrate 1 by chemical bonds or the like, the glass substrate can be adhered to the glass substrate without any additional adhesive layer. In addition, materials such as naphthalene, phosphorus pentachloride, amine compounds, polyalcohols, paraffin and the like may be bonded to the acrylic plate through chemical bonding. Alternatively, the carrier substrate 1 is a metal plate with a rough surface. Specifically, the surface of the carrier substrate 1 for coating the thin film layer is rough, and materials such as naphthalene, phosphorus pentachloride, amine compounds, polyalcohol compounds and paraffin wax can be better adhered to the metal plate.

Further, the encapsulation layer contains SiₓO_{y} and/or SiN, where x≥1 and y≥1. For example, SiₓO_{y} can be SiO, Si₂O₃ or Si₃O₄, SiₓO_{y} or the SiN film has a good barrier to oxygen and water vapor. The encapsulation layer 6 may further include a resin film.

Further, the amine compound is at least one of an aromatic amine compound or acrylamide.

Further, the polyalcohol compound is polyethylene glycol.

Further, the thickness of the film layer 2 is on the order of nanometers or micrometers. The thin film layer 2, as a sacrificial layer, is initially in a solid state and is bonded on the carrier substrate 1, isolating the flexible substrate layer 3 from the carrier substrate 1, and the thickness of the thin film layer 2 is nanometer level or micrometer level. After reaching the melting temperature or the sublimation temperature, it can rapidly melt or sublimate so that the flexible substrate layer 3 and the carrier substrate 1 can be rapidly peeled off.

Further, the flexible substrate layer 3 is a transparent film made of at least one material of polyethylene (PE), polypropylene (PP), polystyrene (PS), polyethylene terephthalate (PET), polyethylene naphthalate (PEN) and polyimide (PI). Preferably, the flexible substrate layer 3 is a transparent film made of a polyimide (PI) material.

Further, the light-emitting layer 5 includes an organic EL layer.

Further, when the thin film layer 2 is made of at least one material of naphthalene and phosphorus pentachloride, vacuum assisted processing is also performed when the thin film layer 2 is heated.

Wherein naphthalene and phosphorus pentachloride are easily sublimation material, when the heating reaches the corresponding sublimation temperature, the sublimation will occur, In the case of heating the thin film layer 2 made of naphthalene and phosphorus pentachloride, vacuum assisted treatment can accelerate the rate of sublimation.

When the carrier substrate 1 is glass substrate, plasma-treatment is performed on one surface of the glass substrate for coating the thin film layer 2 to increase the number and roughness of the hydroxyl groups on the surface of the glass substrate to increase the adhesive force between the thin film layer 2 or evaporated SiO or SiN and the glass.

The present disclosure also provides a flexible OLED display device, which is made by the above-mentioned stripping method of a flexible OLED display device.

Summary, in the stripping method of a flexible OLED display provided by the present disclosure, the carrier substrate 1 is made of glass plate, acrylic plate or rough metal plate, the surface of which is coated with a thin film layer 2 made of at least one material of naphthalene, phosphorus pentachloride, amine compounds, polyalcohol compounds and paraffin, and these materials can be directly bonded with the groups carrying the surface of the carrier substrate 1 by chemical bonds to form an adhesive force so that the film layer 2 and the carrier substrate 1 can be bonded together. The flexible substrate layer 3, the low-temperature polysilicon layer 4, the light-emitting layer 5 and the encapsulation layer 6 are sequentially formed on the film layer 2 to form a flexible OLED display device. Finally, the thin film layer 2 is micro-heated to melt or sublimate the thin film layer 2 to peel off the flexible OLED display device from the carrier substrate 1.

The thin film layer 2 used in the present disclosure can be melted or sublimated by heating the thin film layer 2 to the corresponding melting point temperature or sublimation temperature by itself with low melting point or easy sublimation to separate the flexible OLED display device from the carrier substrate 1. It will not appear difficult to peel off between the flexible substrate layer 3 and the carrier substrate 1 of the display device and will not cause the film layer (e.g., EL layer) in the OLED display device to be broken due to the pulling and improve the yield of the peeling process of the OLED display device.

The foregoing is a further detailed description of the present disclosure in conjunction with specific preferred embodiments, and it should not be considered that the specific implementation of the present disclosure is limited to these descriptions. Those skilled in the art to which the present disclosure pertains may also make some simple deductions or replacements without departing from the concept of the present disclosure and should all consider the scope of protection of the present disclosure.

What is claimed is:

1. A stripping method of a flexible OLED display device, comprising the steps of;
coating a thin film layer on a side of a carrier substrate, wherein the carrier substrate is one of a glass plate, an acrylic plate and a rough metal plate, a material of the thin film layer is at least one of naphthalene, phosphorus pentachloride, amine compounds, polyalcohol compounds and paraffin wax;
forming a flexible substrate layer on the thin film layer;
forming a low-temperature polysilicon layer on the flexible substrate layer;
forming a light-emitting layer on the low-temperature polysilicon layer;
forming an encapsulation layer on the light-emitting layer; and
heating the thin film layer until the flexible substrate layer is peeled off from the carrier substrate to obtain a flexible OLED display device.

2. The stripping method of a flexible OLED display device according to claim 1, wherein the encapsulation layer comprises SiₓO_{y} and/or SiN, where x≥1 and y≥1.

3. The stripping method of a flexible OLED display device according to claim 1, wherein the amine compound is at least one of an aromatic amine compound or acrylamide.

4. The stripping method of a flexible OLED display device according to claim 1, wherein the polyalcohol compound is polyethylene glycol.

5. The stripping method of a flexible OLED display device according to claim 1, wherein the thickness of the thin film layer is nanometer level or micrometer level.

6. The stripping method of a flexible OLED display device according to claim 1, wherein the flexible substrate layer is a transparent film made of at least one material selected from the group consisting of polyethylene, polypropylene, polystyrene, polyethylene terephthalate, polyethylene naphthalate and polyimide.

7. The stripping method of a flexible OLED display device according to claim 1, wherein the light-emitting layer comprises an organic EL layer.

8. The stripping method of a flexible OLED display device according to claim 1, wherein when the thin film layer is made of at least one material of naphthalene and phosphorus pentachloride, vacuum assisted processing is also performed when the thin film layer is heated.

9. The stripping method of a flexible OLED display device according to claim 2, wherein when the carrier substrate is a glass plate, a surface of the glass plate coated with the thin film layer is plasma-treated to increase the number of hydroxyl groups and the roughness of the surface thereof.

10. A stripping method of a flexible OLED display device, comprising the steps of:
coating a thin film layer on a side of a carrier substrate, wherein the carrier substrate is one of a glass plate, an acrylic plate and a rough metal plate, a material of the thin film layer is at least one of naphthalene, phosphorus pentachloride, amine compounds, polyalcohol compounds and paraffin wax;
forming a flexible substrate layer on the thin film layer;
forming a low-temperature polysilicon layer on the flexible substrate layer;
forming a light-emitting layer on the low-temperature polysilicon layer;
forming an encapsulation layer on the light-emitting layer; and
heating the thin film layer until the flexible substrate layer is peeled off from the carrier substrate to obtain a flexible OLED display device;
wherein the encapsulation layer comprises SiₓO_{y} and/or SiN, where x≥1 and y≥1.

11. The stripping method of a flexible OLED display device according to claim 10, wherein the amine compound is at least one of an aromatic amine compound or acrylamide.

12. The stripping method of a flexible OLED display device according to claim 10, wherein the polyalcohol compound is polyethylene glycol.

13. The stripping method of a flexible OLED display device according to claim 10, wherein the thickness of the thin film layer is nanometer level or micrometer level.

14. The stripping method of a flexible OLED display device according to claim 10, wherein the flexible substrate layer is a transparent film made of at least one material selected from the group consisting of polyethylene, polypropylene, polystyrene, polyethylene terephthalate, polyethylene naphthalate and polyimide.

15. The stripping method of a flexible OLED display device according to claim 10, wherein the light-emitting layer comprises an organic EL layer,

16. The stripping method of a flexible OLED display device according to claim 10, wherein when the thin film layer is made of at least one material of naphthalene and phosphorus pentachloride, vacuum assisted processing is also performed when the thin film layer is heated.

17. The stripping method of a flexible OLED display device according to claim 10, wherein when the carrier substrate is a glass plate, a surface of the glass plate coated with the thin film layer is plasma-treated to increase the number of hydroxyl groups and the roughness of the surface thereof.
